(19) United States
(12) Patent Application Publication
(10) Pub. No.: US 2009/0189706 A1
(43) Pub. Date: Jul. 30, 2009

(54) INDUCTANCE-SWITCHABLE DUAL-BAND VOLTAGE CONTROLLED OSCILLATION CIRCUIT

(75) Inventors: Wei-Yang Lee, Taipei (TW); Jean-Fu Kiang, Taipei (TW)

Correspondence Address: PEARNE & GORDON LLP, 1801 EAST 9TH STREET, SUITE 1200, CLEVELAND, OH, 44114-3108, US

(73) Assignee: NATIONAL TAIWAN UNIVERSITY, Taipei (TW)

(21) Appl. No.: 12/142,393

(22) Filed: Jun. 19, 2008

(30) Foreign Application Priority Data
Jan. 25, 2008 (TW) 097102789

(51) Int. Cl. H03B 5/08

(52) U.S. Cl. 331/181

(57) ABSTRACT

An inductance-switchable dual-band voltage-controlled oscillation circuit is proposed, which is designed for integration to a high-frequency signal processing system, such as an ultra-wideband (UWB) circuit system, for providing a dual-band voltage-controlled oscillating signal generating function. The proposed voltage-controlled oscillation circuit is characterized by the use of a switchable inductance circuit architecture in lieu of a switchable capacitive circuit architecture for integration to a fixed-inductance circuit architecture to constitute a variable-inductance LC tuning circuit architecture that allows the provision of a dual-band oscillating signal generating function. Further, a current mirror circuit module is used to maintain the quality factor of the LC tuning circuit in both operating modes; a buffer-stage circuit architecture is used to achieve low power consumption, low phase noise, and broad tuning range.

### BACKGROUND OF THE INVENTION

1. Field of the Invention

This invention relates to electronic circuitry technology, and more particularly, to an inductance-switchable dual-band voltage-controlled oscillation circuit which is designed for integration to a high-frequency signal processing system, such as an ultra-wide band (UWB) circuit system, for providing a dual-band voltage-controlled oscillating signal generating function.

2. Description of Related Art

With the advent of wireless digital communication technologies, such as wireless networking, mobile phones, GPS (Global Positioning System), and digital TV, the design and manufacture of high-speed digital circuit boards that operate with signals within the gigahertz (GHz) range is in high demand in the electronics industry. Nowadays, the operating frequency of high-speed digital circuitry has advanced to the range from 3.1 GHz to 10.6 GHz.

In the design of high-speed digital circuitry, voltage-controlled oscillator (VCO) is an important component that can generate an oscillating signal whose frequency is controllable by an input control voltage. In practical applications, UWB circuit systems often require the use of multiple output frequencies for use under various operating conditions. For this sake, there exists a need for a multi-band VCO circuit that can generate two or more output frequencies depending on different operating conditions.

Presently in the electronics industry, various types of multi-band VCO circuits have been developed. For high-performance applications, multi-band VCO circuits are required to have low power consumption, low phase noise, and broad tuning range.

### SUMMARY OF THE INVENTION

It is therefore an objective of this invention to provide an inductance-switchable dual-band voltage-controlled oscillation circuit that have low power consumption, low phase noise, and broad tuning range.

The inductance-switchable dual-band voltage-controlled oscillation circuit according to the invention is designed for integration to a high-frequency signal processing system, such as an ultra-wide band (UWB) circuit system, for providing a dual-band voltage-controlled oscillating signal generating function.

The architecture of the inductance-switchable dual-band voltage-controlled oscillation circuit according to the invention comprises: (A) a capacitive circuit module; (B) an inductance switching circuit module; (C) a fixed-inductance circuit module; (D) a cross-coupled switching circuit module; and (E) a current mirror circuit module; and can further comprise: (F) a first buffer-stage circuit module and a second buffer-stage circuit module.

The inductance-switchable dual-band voltage-controlled oscillation circuit according to the invention is characterized by the use of a switchable inductance circuit architecture in lieu of a switchable capacitance circuit architecture for integration to a fixed-inductance circuit architecture to constitute a variable-inductance LC tuning circuit architecture that allows the provision of a dual-band oscillating signal generating function. Further, a current mirror circuit module is used to maintain the quality factor of the LC tuning circuit in both operating modes; a buffer-stage circuit architecture is used to achieve low power consumption, low phase noise, and broad tuning range. These features allow the invention to be more advantageous to use than prior art.

### BRIEF DESCRIPTION OF DRAWINGS

The invention can be more fully understood by reading the following detailed description of the preferred embodiments, with reference made to the accompanying drawings, wherein:

FIG. 1 is a schematic diagram showing the I/O functional model of the VCO circuit of the invention; (In FIG. 1, change “DUal” to “Dual”, change “Voltage Controlled” to “Voltage-Controlled”

FIG. 2 is a schematic diagram showing the circuit architecture of the VCO circuit of the invention;

FIG. 3A shows an equivalent circuit of the switching element in the inductance switching circuit module of the VCO circuit of the invention when switched to the OFF state;

FIG. 3B shows an equivalent circuit of the switching element in the inductance switching circuit module of the VCO circuit of the invention when switched to the ON state;

FIGS. 4A-4B are graphs showing phase noise characteristics versus offset frequency of the VCO circuit of the invention in low-band mode (3.96 GHz) and high-band mode (7.128 GHz), respectively;

FIGS. 5A-5B are graphs showing the tuning range characteristics of the VCO circuit of the invention in low-band mode (3.96 GHz) and high-band mode (7.128 GHz), respectively;

FIGS. 6A-6B are graphs showing the output power characteristics of the VCO circuit of the invention in low-band mode (3.96 GHz) and high-band mode (7.128 GHz), respectively; and

FIG. 6C is a graph showing the quality factor versus operating frequency of the VCO circuit of the invention.

### DETAILED DESCRIPTION OF PREFERRED EMBODIMENTS

The inductance-switchable dual-band voltage-controlled oscillation circuit according to the invention is disclosed in full details by way of preferred embodiments in the following with reference to the accompanying drawings.

### Application and Function of the Invention

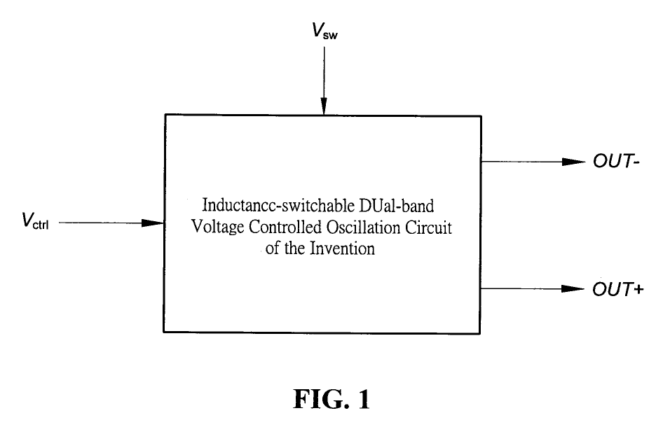

FIG. 1 is a schematic diagram showing the input/output (I/O) functional model of the inductance-switchable dual-band voltage-controlled oscillation circuit according to the invention (which is here encapsulated in a box indicated by the reference numeral 100, and is hereinafter referred in short as VCO circuit). As shown, the VCO circuit of the invention 100 is designed with an I/O interface having a control-voltage input port V_{ctrl}, a switching-voltage input port V_{sw}, and a pair of differential output ports including a positive differential output port (OUT+) and a negative differential output port (OUT−).

In actual operation, the VCO circuit of the invention 100 is capable of providing a dual-band voltage-controlled oscillating signal generating function that can operate in two different operating modes: a low-band mode and a high-band mode. In practical applications, for example, the low-band mode is around 3.96 GHz, while the high-band mode is around 7.128 GHz, which are variably controllable by a switching voltage V_{sw}. In this embodiment, when V_{sw}=0 V, the VCO circuit of the invention 100 outputs an oscillating signal of 3.96 GHz ; and when V_{sw}=1.8 V, the output oscillating signal has a frequency of 7.128 GHz.

In practical applications, the VCO circuit of the invention 100 can be integrated to a gigahertz signal processing system, such as a frequency synthesizer or a PLL (phase-locked loop) circuit in an ultra-wide band (UWB) signal processing system, for selectively generating two oscillating signals of 3.96 GHz and 7.128 GHz, respectively.

### Architecture of the Invention

As shown in FIG. 2, the architecture of VCO circuit of the invention 100 comprises: (A) a capacitive circuit module 110; (B) an inductance switching circuit module 120; (C) a fixed-inductance circuit module 130; (D) a cross-coupled switching circuit module 140; and (E) a current mirror circuit module 150; and can further comprise: (F) a first buffer-stage circuit module 210 and a second buffer-stage circuit module 220. Firstly, the respective attributes and functions of these constituent components of the invention are described in details in the following.

### Capacitive Circuit Module 110

The capacitive circuit module 110 is composed of at least two serially-connected capacitive elements, including a first capacitive element (C₁) 111 and a second capacitive element (C₂) 112. In circuit arrangement, the first capacitive element (C₁) 111 has its two terminal ends connected to the control-voltage input port V_{ctrl} and a first node (N1), respectively; while the second capacitive element (C₂) 112 has its two terminal ends connected to the control-voltage input port V_{ctrl} and a second node (N2), respectively. The first node (N1) and the second node (N2) are connected to the positive differential output port (OUT+) and the negative differential output port (OUT−), respectively.

### Inductance Switching Circuit Module 120

The inductance switching circuit module 120 is composed of a switching element (which is in this embodiment implemented with an NMOS transistor 121) and an inductive circuit (which is in this embodiment implemented with a pair of inductors including a first inductor (L₁) 122 and a second inductor (L₂) 123). In circuit arrangement, the NMOS transistor 121 has its gate (control terminal) connected to the switching-voltage input port V_{sw}, its source (first connecting terminal) connected to one end of the first inductor (L₁) 122, and its drain (second connecting terminal) connected to one end of the second inductor (L₂) 123. The first inductor (L₁) 122 is interconnected between the first node (N1) and the source of the NMOS transistor 121; while the second inductor (L₂) 123 is interconnected between the second node (N2) and the drain of the NMOS transistor 121.

In operation, the NMOS transistor 121 is controlled by the switching voltage V_{sw} applied to its gate for selectively connecting or disconnecting the first inductor (L₁) 122 and the second inductor (L₂) 123. In actual implementation, for example, when V_{sw}=0 V, the NMOS transistor 121 is switched to OFF state such that the first inductor (L₁) 122 is electrically disconnected from the second inductor (L₂) 123. On the other hand, when V_{sw}=1.8V, the NMOS transistor 121 is switched to ON state such that the first inductor (L₁) 122 is electrically connected to the second inductor (L₂) 123, effectively adding an inductance of (L₁+L₂) between the first node (N1) and the second node (N2).

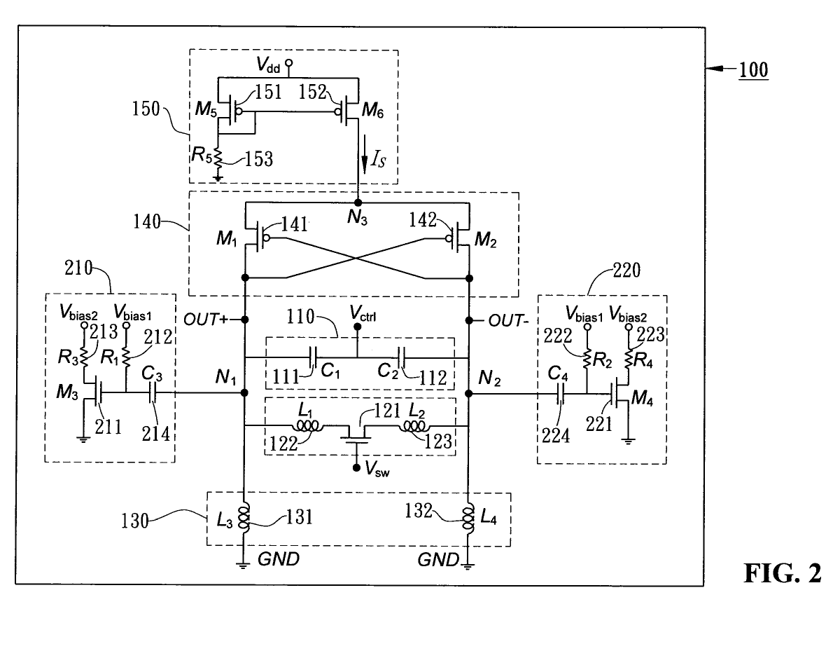

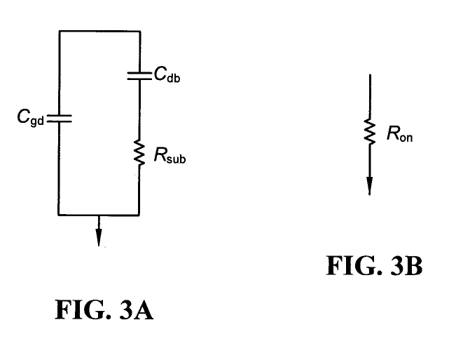

FIG. 3A shows an equivalent circuit of the NMOS transistor 121 in the OFF state, wherein C_{db} represents the drain-to-substrate capacitance of the NMOS transistor 121; C_{gd} represents the drain-to-gate capacitance of the NMOS transistor 121; and R_{sub} represents the drain-to-substrate resistance of the NMOS transistor 121.

In addition, FIG. 3B shows an equivalent circuit of the NMOS transistor 121 in the ON state; in which Rₒₙ represents the drain-to-substrate resistance of the NMOS transistor 121.

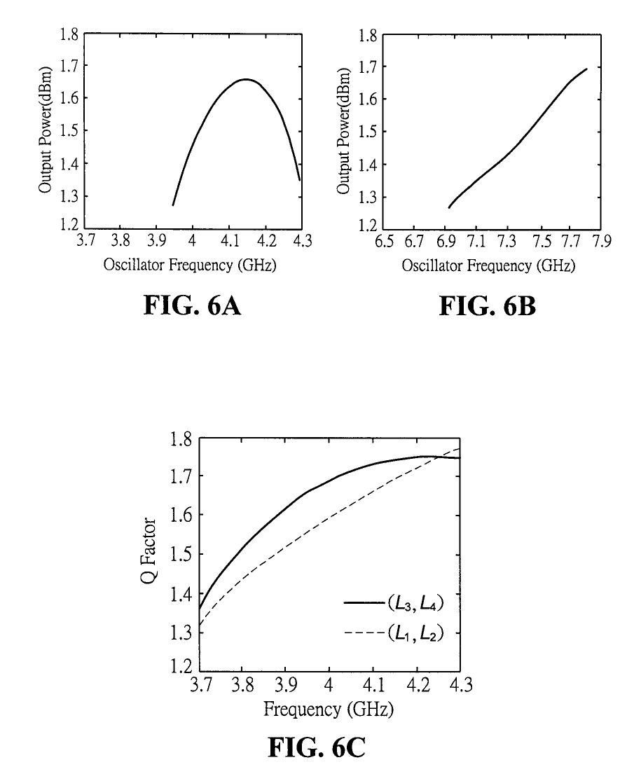

Further, as shown in FIG. 6C, the combined inductive circuit (L₁+L₂) of the inductance switching circuit module 120 has a quality factor of Q=6.85 in the low-band mode of 3.96 GHz, and Q=10.01 in the high-band mode of 7.128 GHz.

### Fixed-Inductance Circuit Module 130

The fixed-inductance circuit module 130 is composed of two inductive elements, including a third inductor (L₃) 131 and a fourth inductor (L₄) 132. In circuit arrangement, the third inductor (L₃) 131 is interconnected between the first node (N1) and a grounding point GND, while the fourth inductor (L₄) 132 is interconnected between the second node (N2) and the grounding point GND. This fixed-inductance circuit module 130 operates in such a manner that when the NMOS transistor 121 is switched to the ON state (ON), it will combine with the first inductor (L₁) 122 and the second inductor (L₂) 123 in the inductance switching circuit module 120 to constitute an augmented inductive circuit (L₁, L₂, L₃, L₄).

As shown in FIG. 6C, the combined circuit of the two inductors (L₃, L₄) in the fixed-inductance circuit module 130 has a quality factor of Q=9.08 in the low-band mode of 3.96 GHz, and Q=12.1 in the high-band mode of 7.128 GHz.

### Cross-Coupled Switching Circuit Module 140

The cross-coupled switching circuit module 140 is composed of a cross-coupled pair of switching elements (which are in this embodiment implemented with a pair of PMOS transistors (M₁, M₂) 141, 142, which are interconnected in such a manner that their respective gate (control terminals) is connected to the source of the other, their drains (second connecting terminals) are connected together to a third node (N3), and their sources (first connecting terminals) are connected to the first node (N1) and the second node (N2), respectively. With this circuit arrangement, the cross-coupled switching circuit module 140 is capable of providing an intercrossed switching function for the output signal at the positive differential output port (OUT+) and the output signal at the negative differential output port (OUT−).

In actual implementation, the cross-coupled switching circuit module 140 can be implemented with either PMOS or NMOS transistors. The PMOS implementation has the advantages of smaller circuit layout area, higher transconductance, and lower phase noise; while the NMOS implementation has the advantages of small 1/f noise, lower hot carrier white noise, and lower power consumption.

### Current Mirror Circuit Module 150

The current mirror circuit module 150 is capable of supplying an electrical current Iₛ of constant magnitude to the third node (N3) irrespective of whether operating in the low-band mode or high-band mode. The architecture of this current mirror circuit module 150 is composed of two PMOS transistors, including a master PMOS transistor (M₅) 151, a mirrored PMOS transistor (M₆) 152, and a resistor (R₅) 153. Since this current mirror circuit module 150 is based on a conventional circuit whose function and architecture are well known, detailed description thereof will not be given in this specification.

In operation, the current mirror circuit module 150 supplies an electrical current Iₛ whose magnitude remains constant irrespective of whether operating in the low-band mode (3.96 GHz) or high-band mode (7.128 GHz). In addition, the mirrored PMOS transistor (M₆) 152 can provide an equivalent large resistance, which allows the VCO circuit of the invention 100 to have a constant quality factor Q irrespective of operating with the tuning circuit (C₁, C₂, L₃, L₄) in the low-band mode or with the augmented tuning circuit (C₁, C₂, L₁, L₂, L₃, L₄) in the high-band mode.

### First Buffer-Stage Circuit Module 210 and Second Buffer-Stage Circuit Module 220

The first buffer-stage circuit module 210 is composed of a switching element 211 (which is implemented with an NMOS transistor M₃ in the embodiment of FIG. 2), a resistor (R₁) 212, a resistor (R₃) 213, and a capacitor (C₃) 214. In circuit arrangement, the first buffer-stage circuit module 210 is coupled via the capacitor (C₃) 214 to the first node (N1), which is also the positive differential output port (OUT+), for providing a buffer effect to the output oscillating signal at the positive differential output port (OUT+).

Similarly, the second buffer-stage circuit module 220 is composed of a switching element 221 (which is implemented with an NMOS transistor M₄ in the embodiment of FIG. 2), a resistor (R₂) 222, a resistor (R₄) 223, and a capacitor (C₄) 224. In circuit arrangement, the second buffer-stage circuit module 220 is coupled via the capacitor (C₄) 224 to the second node (N2), which is also the negative differential output port (OUT−), for providing a buffer effect to the output oscillating signal at the negative differential output port (OUT−).

Since both the first buffer-stage circuit module 210 and the second buffer-stage circuit module 220 are based on conventional circuitry whose function and architecture are well known, detailed description thereof will not be given in this specification.

### Operation of the Invention

In operation, the VCO circuit of the invention 100 is capable of providing a dual-band voltage-controlled oscillating signal generating function for operation in either the low-band mode of 3.96 GHz or the high-band mode of 7.128 GHz. The switching of these two modes is controlled by the switching voltage V_{sw} in a manner described as follows.

When V_{sw}=0 V, the NMOS transistor 121 is switched to the OFF state such that the first inductor (L₁) 122 and the second inductor (L₂) 123 are electrically disconnected from each other, or effectively being functionally disabled. As a result, the VCO circuit of the invention 100 will operate on the LC circuit (C₁, C₂, L₃, L₄) and thereby provide a low-band output oscillating signal whose frequency, represented by fₒ_{_{—}}_{off}, is determined as follows:

$${f}_{o\_off} = \frac{1}{2 π \sqrt{{L}_{3} {C}_{1}}} ( note \text{:} {C}_{1} = {C}_{2} and {L}_{3} = {L}_{4} )$$

On the other hand, when V_{sw}=1.8 V, the NMOS transistor 121 is switched to the ON state such that the first inductor (L₁) 122 and the second inductor (L₂) 123 are electrically connected to each other, effectively providing an additional inductance (L₁+L₂) between the first node (N1) and the second node (N2). As a result, the VCO circuit of the invention 100 will operate on the augmented LC circuit (C₁, C₂, L₁, L₂, L₃, L₄) and thereby provide a high-band output oscillating signal whose frequency, represented by fₒ_{_{—}}ₒₙ, is determined as follows:

$${f}_{o\_on} = \frac{1}{2 π \sqrt{{L}_{t} {C}_{1}}}$$

where

Lₜ=L₃∥L₁ (where Lₜ is the equivalent inductance of the parallel connected L₃ and L₁).

### Operating Characteristics of the Invention

The following is a description of some operating characteristics of the VCO circuit of the invention 100 based on circuit simulation and experimentation, which include: (1) phase noise (PN); (2) tuning range; (3) output power; and (4) figure of merit (FOM).

### (1) Phase Noise (PN)

Theoretically, for a VCO circuit based on an LC tuning circuit, its phase noise (PN) is related to the oscillating frequency (fₒ) as follows:

$$P N ( {f}_{o} ) = \frac{2 {kTR}_{eq} F}{{V}_{s}^{2}} \cdot {( \frac{{f}_{o}}{2 Q Δ f} )}^{2} \cdot ( 1 + \frac{Δ {f}_{1 / f}^{3}}{Δ f} )$$

where

k is Boltzmann constant;

T is absolute temperature;

R_{eq} is the equivalent resistance of the LC tuning circuit (C₁, C₂, L₁, L₂, L₃, L₄);

F is excess noise factor;

Vₛ is the magnitude of the output oscillating signal

Q is the quality factor of the LC tuning circuit (C₁, C₂, L₁, L₂, L₃, L₄);

Δf is offset frequency;

Δf_{1/f3} is corner frequency of flicker noise.

The above equation is based on principle and theory disclosed in the following technical paper: “A 5.3 GHz low-phase-noise LC VCO with harmonic filtering resistor” authored by L. Wang et al. and published in IEEE Proc. ISCAS, May 2006, so detailed description thereof will not be given in this specification.

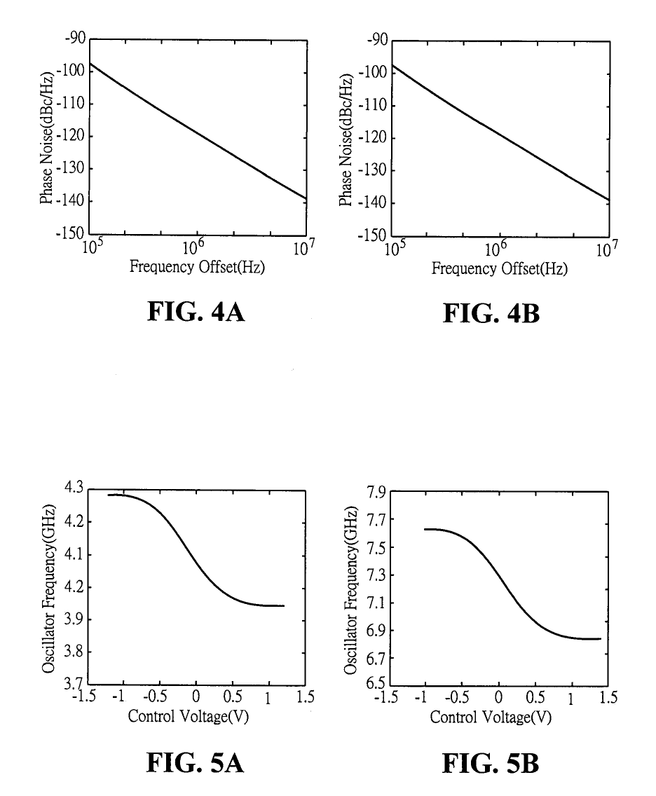

FIGS. 4A-4B are graphs showing phase noise characteristics versus offset frequency in the low-band mode (3.96 GHz) and high-band mode (7.128 GHz), respectively. As shown in FIG. 4A, when the VCO circuit of the invention 100 is operating in the low-band mode of 3.96 GHz with an offset frequency of 1 MHz, the phase noise is about −118.2 dBc/Hz. Further, as shown in FIG. 4B, when the VCO circuit of the invention 100 is operating in the high-band mode of 7.128 GHz with the same offset frequency of 1 MHz, the phase noise is about −117.659 dBc/Hz.

### (2) Tuning Range

FIGS. 5A-5B are graphs showing the tuning range characteristics of the VCO circuit of the invention 100 in the low-band mode (3.96 GHz) and high-band mode (7.128 GHz), respectively. As shown in FIG. 5A, when the VCO circuit of the invention 100 is operating in the low-band mode of 3.96 GHz, it provides a tuning range of about 8%. Further, as shown in FIG. 5B, when the VCO circuit of the invention 100 is operating in the high-band mode of 7.128 GHz, it provides a tuning range of about 11%.

### (3) Output Power

FIGS. 6A-6B are graphs showing the output power characteristics of the VCO circuit of the invention 100 in the low-band mode (3.96 GHz) and high-band mode (7.128 GHz), respectively. As shown in FIG. 6A, when the VCO circuit of the invention 100 is operating in the low-band mode of 3.96 GHz, it provides an output power of about 1.325 dBm. Further, as shown in FIG. 6B, when the VCO circuit of the invention 100 is operating in the high-band mode of 7.128 GHz, it provides an output power of about 1.855 dBm.

### (3) Figure of Merit (FOM)

In the performance evaluation of VCO circuits, a widely accepted standard is the figure of merit (FOM), which evaluates the performance of a VCO circuit based on the following formula:

$$F O M = P N ( Δ f ) - 20 log ( \frac{{f}_{o}}{Δ f} ) + 10 log ( \frac{{P}_{dc}}{1 m W} )$$

where

f₀ is carrier frequency;

Δf is offset frequency;

PN(Δf) represents the phase noise at an offset frequency Δf;

P_{dc} is power consumption (unit: mW).

The above formula is based on principle and theory disclosed in the following technical paper: “A low-phase-noise and low-power-multiband CMOS voltage-controlled oscillator” authored by Z. Li et al. and published in IEEE J. Solid-State Circuits, vol. 40, no. 6, pp. 1296-1302, June 2005.

Based on the above FOM formula, it can be calculated that the invention can provide an FOM of 180.6 dB in the low-band mode of 3.96 GHz, and an FOM of 185.2 dB in the high-band mode of 7.128 GHz.

In conclusion, the invention provides an inductance-switchable dual-band voltage-controlled oscillation circuit which is characterized by the use of a switchable inductance circuit architecture in lieu of a switchable capacitive circuit architecture for integration to a fixed-inductance circuit architecture to constitute a variable-inductance LC tuning circuit architecture that allows the provision of a dual-band oscillating signal generating function. Further, a current mirror circuit module is used to maintain the quality factor of the LC tuning circuit in both operating modes; a buffer-stage circuit architecture is used to have low power consumption, low phase noise, and broad tuning range. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. An inductance-switchable dual-band voltage-controlled oscillation circuit which includes an input/output interface having a control-voltage input port, a switching-voltage input port, and a pair of differential output ports including a positive differential output port and a negative differential output port, for providing a dual-band voltage-controlled oscillating signal generating function in dual-band modes including a low-band mode and a high-band mode;
the inductance-switchable dual-band voltage controlled oscillation circuit comprising:
a capacitive circuit module, which includes at least a serially-connected pair of capacitive elements including a first capacitive element and a second capacitive element, wherein the first capacitive element has two terminal ends connected to the control-voltage input port and a first node, respectively, while the second capacitive element has two terminal ends connected to the control-voltage input port and a second node, respectively; and wherein the first node and the second node are connected to the positive differential output port and the negative differential output port, respectively;
an inductance switching circuit module, which includes a switching element and two inductive elements, wherein the switching element is capable of being switched by a switching voltage from the switching-voltage input port to electrically connect the inductive element between the first node and the second node;
a fixed-inductance circuit module, which includes a first inductive element and a second inductive element; wherein the first inductive element is interconnected between the first node and a grounding point, while the second inductive element is interconnected between the second node and the grounding point; the fixed-inductance circuit module in combination with the inductance switching circuit module and the capacitive circuit module to constitute an inductance-variable tuning circuit;
a cross-coupled switching circuit module, which includes a cross-connected pair of switching elements, wherein each switching element has a control terminal, a first connecting terminal, and a second connecting terminal, and wherein the switching elements have their control terminals connected to the first connecting terminal of the other, their second connecting terminals connected to a third node, and their first connecting terminals connected to the first node and the second node, respectively; and
a current mirror circuit module, which is capable of supplying an electrical current of constant magnitude to the third node in both the low-band mode and high-band mode.

2. The inductance-switchable dual-band voltage-controlled oscillation circuit as recited in claim 1, further comprising:
a first buffer-stage circuit module, which is coupled to the first node for providing a buffer effect to an output oscillating signal from the first node; and
a second buffer-stage circuit module, which is coupled to the second node for providing a buffer effect to an output oscillating signal from the second node.

3. The inductance-switchable dual-band voltage-controlled oscillation circuit as recited in claim 1, wherein the switching element in the inductance switching circuit module is an NMOS transistor.

4. The inductance-switchable dual-band voltage-controlled oscillation circuit as recited in claim 1, wherein the cross-coupled switching circuit module is an NMOS-based crossed switching circuit.

5. The inductance-switchable dual-band voltage-controlled oscillation circuit as recited in claim 1, wherein the cross-coupled switching circuit module is a PMOS-based crossed switching circuit.

6. The inductance-switchable dual-band voltage-controlled oscillation circuit as recited in claim 1, wherein the current mirror circuit module is a PMOS-based current mirror circuit.

7. The inductance-switchable dual-band voltage-controlled oscillation circuit as recited in claim 2, wherein the first buffer-stage circuit module is an NMOS-based buffer-stage circuit.

8. The inductance-switchable dual-band voltage-controlled oscillation circuit as recited in claim 2, wherein the second buffer-stage circuit module is an NMOS-based buffer-stage circuit.

9. An inductance-switchable dual-band voltage-controlled oscillation circuit which includes an input/output interface having a control-voltage input port, a switching-voltage input port, and a pair of differential output ports including a positive differential output port and a negative differential output port, for providing a dual-band voltage-controlled oscillating signal generating function in dual-band modes including a low-band mode and a high-band mode;
the inductance-switchable dual-band voltage-controlled oscillation circuit comprising:
a capacitive circuit module, which includes at least a serially-connected pair of capacitive elements including a first capacitive element and a second capacitive element, wherein the first capacitive element has two terminal ends connected to the control-voltage input port and a first node, respectively, while the second capacitive element has two terminal ends connected to the control-voltage input port and a second node, respectively; and wherein the first node and the second node are connected to the positive differential output port and the negative differential output port, respectively;
an inductance switching circuit module, which includes a switching element and at least one inductive element, wherein the switching element is capable of being switched by a switching voltage from the switching-voltage input port to electrically connect the inductive elements between the first node and the second node;
a fixed-inductance circuit module, which includes at least a first inductive element and a second inductive element; wherein the first inductive element is interconnected between the first node and a grounding point, while the second inductive element is interconnected between the second node and the grounding point; the fixed-inductance circuit module in combination with the inductance switching circuit module and the capacitive circuit module constituting an inductance-variable tuning circuit;
a cross-coupled switching circuit module, which includes a cross-connected pair of switching elements, wherein each switching element has a control terminal, a first connecting terminal, and a second connecting terminal, and wherein the switching elements have their control terminals connected to the first connecting terminal of the other, their second connecting terminals connected to a third node, and their first connecting terminals connected to the first node and the second node, respectively;
a current mirror circuit module, which is capable of supplying an electrical current of constant magnitude to the third node in both the low-band mode and high-band mode;
a first buffer-stage circuit module, which is coupled to the first node for providing a buffer effect to an output oscillating signal from the first node; and
a second buffer-stage circuit module, which is coupled to the second node for providing a buffer effect to an output oscillating signal from the second node.

10. The inductance-switchable dual-band voltage-controlled oscillation circuit as recited in claim 9, wherein the switching element in the inductance switching circuit module is an NMOS transistor.

11. The inductance-switchable dual-band voltage-controlled oscillation circuit as recited in claim 9, wherein the cross-coupled switching circuit module is an NMOS-based crossed switching circuit.

12. The inductance-switchable dual-band voltage-controlled oscillation circuit as recited in claim 9, wherein the cross-coupled switching circuit module is a PMOS-based crossed switching circuit.

13. The inductance-switchable dual-band voltage-controlled oscillation circuit as recited in claim 9, wherein the current mirror circuit module is a PMOS-based current mirror circuit.

14. The inductance-switchable dual-band voltage-controlled oscillation circuit as recited in claim 9, wherein the first buffer-stage circuit module is an NMOS-based buffer-stage circuit.

15. The inductance-switchable dual-band voltage-controlled oscillation circuit as recited in claim 9, wherein the second buffer-stage circuit module is an NMOS-based buffer-stage circuit.

16. An inductance-switchable dual-band voltage-controlled oscillation circuit which includes an input/output interface having a control-voltage input port, a switching-voltage input port, and a pair of differential output ports including a positive differential output port and a negative differential output port, for providing a dual-band voltage-controlled oscillating signal generating function in dual-band modes including a low-band mode and a high-band mode;
the inductance-switchable dual-band voltage-controlled oscillation circuit comprising:
a capacitive circuit module, which includes at least a serially-connected pair of capacitive elements including a first capacitive element and a second capacitive element, wherein the first capacitive element has two terminal ends connected to the control-voltage input port and a first node, respectively, while the second capacitive element has two terminal ends connected to the control-voltage input port and a second node, respectively; and wherein the first node and the second node are connected to the positive differential output port and the negative differential output port, respectively;
an inductance switching circuit module, which includes an NMOS-based switching element and at least one inductive element, wherein the switching element is capable of being switched by a switching voltage from the switching-voltage input port to electrically connect the inductive elements between the first node and the second node;
a fixed-inductance circuit module, which includes at least a first inductive element and a second inductive element; wherein the first inductive element is interconnected between the first node and a grounding point, while the second inductive element is interconnected between the second node and the grounding point; the fixed-inductance circuit module in combination with the inductance switching circuit module and the capacitive circuit module constituting an inductance-variable tuning circuit;
a cross-coupled switching circuit module, which includes a cross-connected pair of PMOS-based switching elements, wherein each switching element has a control terminal, a first connecting terminal, and a second connecting terminal, and wherein the switching elements have their respective control terminals connected to the first connecting terminal of the other, their second connecting terminals connected to a third node, and their first connecting terminals connected to the first node and the second node, respectively; and
a current mirror circuit module, which is capable of supplying an electrical current of constant magnitude to the third node in both the low-band mode and high-band mode.

17. The inductance-switchable dual-band voltage-controlled oscillation circuit as recited in claim 16, further comprising:
a first buffer-stage circuit module, which is coupled to the first node for providing a buffer effect to the output oscillating signal from the first node; and
a second buffer-stage circuit module, which is coupled to the second node for providing a buffer effect to the output oscillating signal from the second node.

18. The inductance-switchable dual-band voltage-controlled oscillation circuit as recited in claim 16, wherein the current mirror circuit module is a PMOS-based current mirror circuit.

19. The inductance-switchable dual-band voltage-controlled oscillation circuit as recited in claim 17, wherein the first buffer-stage circuit module is an NMOS-based buffer-stage circuit.

20. The inductance-switchable dual-band voltage-controlled oscillation circuit as recited in claim 17, wherein the second buffer-stage circuit module is an NMOS-based buffer-stage circuit.
